(19) United States
(12) Patent Application Publication
(10) Pub. No.: US 2024/0266354 A1
(43) Pub. Date: Aug. 8, 2024

(54) DISPLAY DEVICE

(71) Applicant: Samsung Display Co., Ltd., Yongin-Si (KR)

(72) Inventors: KEUNWOO KIM, Yongin-si (KR); DOO-NA KIM, Yongin-si (KR); SANGSUB KIM, Yongin-si (KR); BUMMO SUNG, Yongin-si (KR); SANGGUN CHOI, Yongin-si (KR)

(21) Appl. No.: 18/424,907

(22) Filed: Jan. 29, 2024

(30) Foreign Application Priority Data
Feb. 3, 2023 (KR) 10-2023-0014928

(51) Int. Cl. H01L 27/12

(52) U.S. Cl. CPC H01L 27/1222; H01L 27/124; H01L 27/1255

(57) ABSTRACT

A display device includes: a substrate, a first active pattern disposed on the substrate and including a first channel region, a second channel region spaced apart from each other, and a first common conductive region positioned between the first channel region and the second channel region, a second active pattern disposed on the substrate, spaced apart from the first active pattern, and including a third channel region, a fourth channel region spaced apart from each other, and a second common conductive region positioned between the third channel region and the fourth channel region, a first gate layer disposed on the first and second active patterns and including a first electrode overlapping the first active pattern, and a second gate layer disposed on the first gate layer and including a second electrode overlapping the second active pattern.

### CROSS-REFERENCE TO RELATED APPLICATION

This application claims priority to and benefits of Korean Patent Application No. 10-2023-0014928 under 35 U.S.C. § 119, filed on Feb. 3, 2023, in the Korean Intellectual Property Office (KIPO), the entire contents of which are hereby incorporated by reference.

### BACKGROUND

### 1. Field

Embodiments generally provide a display device. More particularly, embodiments relate to a pixel included in the display device.

### 2. Description of the Related Art

Research on minimizing battery consumption of various electronic devices widely used in real life, such as smartphone, laptop computer, tablet PCs, and the like is ongoing.

These electronic devices may include display devices. Battery consumption of electronic devices can be minimized by minimizing power consumption of the display device. For example, in order to reduce the power consumption of the display device, a low-frequency driving method for driving the display device at a relatively low-frequency has been proposed.

When the display device is driven by the low-frequency driving method, a leakage current in a pixel increases as the period of one frame increases, and a difference in luminance of a corresponding pixel between two frames may occur due to such the leakage current, resulting in a flicker phenomenon.

### SUMMARY

Embodiments provide a display device having improved a low-frequency characteristic.

A display device according to embodiments of the present disclosure includes a substrate, a first active pattern disposed on the substrate and including a first channel region, a second channel region spaced apart from each other, and a first common conductive region positioned between the first channel region and the second channel region, a second active pattern disposed on the substrate, spaced apart from the first active pattern, and including a third channel region, a fourth channel region spaced apart from each other, and a second common conductive region positioned between the third channel region and the fourth channel region, a first gate layer disposed on the first and second active patterns and including a first electrode overlapping the first active pattern, and a second gate layer disposed on the first gate layer and including a second electrode overlapping the second active pattern.

In an embodiment, the second electrode may be spaced apart from the first electrode in a plan view.

In an embodiment, the first electrode may overlap the first common conductive region and the second electrode may overlap the second common conductive region in a plan view.

In an embodiment, the first electrode may constitute a first capacitor together with the first common conductive region and the second electrode may constitute a second capacitor together with the second common conductive region.

In an embodiment, a distance between the first active pattern and the first electrode may be smaller than a distance between the second active pattern and the second electrode.

In an embodiment, the first active pattern and the second active pattern may be integrally formed and constitute a first active layer.

In an embodiment, the display device may further include a second active layer spaced apart from the first active layer and two stabilization electrodes disposed on the second active layer and overlapping the second active layer. The second active layer and the stabilization electrodes may constitute a third capacitor and a fourth capacitor, respectively.

In an embodiment, a capacitance of the third capacitor may be different from a capacitance of the fourth capacitor.

In an embodiment, the first gate layer may include a first gate electrode partially overlapping the first active pattern and a second gate electrode partially overlapping the second active pattern.

In an embodiment, the first gate electrode may overlap the first channel region and the second channel region of the first active pattern, and the second gate electrode may overlap the third channel region and the fourth channel region of the second active pattern.

In an embodiment, the display device may further include a power line disposed on the second gate layer and connected to each of the first electrode and the second electrode.

A display device according to embodiments of the present disclosure includes a substrate, a first active pattern disposed on the substrate and including a first channel region, a second channel region spaced apart from each other, and a first common conductive region positioned between the first channel region and the second channel region, a second active pattern disposed on the substrate, spaced apart from the first active pattern, and including a third channel region, a fourth channel region spaced apart from each other, and a second common conductive region positioned between the third channel region and the fourth channel region and having a smaller area than the first common conductive region, a first gate layer disposed on the first and second active patterns, and a second gate layer disposed on the first gate layer and including a common capacitor electrode overlapping the first and second active patterns.

In an embodiment, the common capacitor electrode may overlap the first common conductive region and the second common conductive region in a plan view.

In an embodiment, the first active pattern and the second active pattern may be integrally formed and constitute an active layer.

In an embodiment, the common capacitor electrode may constitute a first capacitor together with the first common conductive region and may constitute a second capacitor together with the second common conductive region.

In an embodiment, an area where the common capacitor electrode and the first common conductive region overlap may be greater than an area where the common capacitor electrode and the second common conductive region overlap.

In an embodiment, a range of a ratio of the area where the common capacitor electrode and the first common conductive region overlap to the area where the common capacitor electrode and the second common conductive region overlap may be greater than about 1 and smaller than about 5.

In an embodiment, the first gate layer may include a first gate electrode partially overlapping the first active pattern and a second gate electrode partially overlapping the second active pattern. The first gate electrode and the second gate electrode may be spaced apart from each other.

In an embodiment, the first gate electrode may overlap the first channel region and the second channel region of the first active pattern, and the second gate electrode may overlap the third channel region and the fourth channel region of the second active pattern.

In an embodiment, the display device may further include a power line disposed on the second gate layer and connected to the common capacitor electrode.

In a display device according embodiments, the display device may further include a first capacitor and a second capacitor in addition to a storage capacitor and a hold capacitor. A voltage of a first common node may be maintained relatively constant due to the first capacitor. Similarly, a voltage of a second common node may be maintained relatively constant due to the second capacitor. That is, the first capacitor can prevent leakage current of a third transistor, and the second capacitor can prevent leakage current of a fourth transistor. Accordingly, the first capacitor and the second capacitor may maintain a constant voltage of the storage capacitor. Accordingly, a low-frequency characteristic of the display device can be improved.

In this case, since a distance between a first active pattern and a first electrode is smaller than a distance between a second active pattern and a second electrode, the capacitance of the first capacitor may be greater than the capacitance of the second capacitor. Alternatively, since an area where a common capacitor electrode and a first common conductive region overlap is greater than an area where the common capacitor electrode and a second common conductive region overlap, the capacitance of the first capacitor may be greater than the capacitance of the second capacitor.

A voltage of the storage capacitor may be relatively more influenced by the first capacitor than by the second capacitor. Therefore, by making the capacitance of the first capacitor greater than the capacitance of the second capacitor, the leakage current of the third transistor can be reduced to be greater than the leakage current of the fourth transistor. As a result, the voltage of the storage capacitor may be maintained constant, and the luminance of the display device may not decrease. In addition, since the flicker phenomenon does not occur, low-frequency characteristics of the display device can be improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to an embodiment of the present disclosure.

FIG. 2 is a circuit diagram for explaining an example of a pixel included in the display device of FIG. 1.

FIG. 3 is a plan view illustrating a display device according to an embodiment of the present disclosure.

FIG. 4 is a layout view illustrating an active layer included in a pixel.

FIG. 5 is a layout view illustrating a first gate layer included in a pixel.

FIG. 6 is a layout view illustrating the active layer of FIG. 4 and the first gate layer of FIG. 5.

FIG. 7 is a layout view illustrating a second gate layer included in a pixel.

FIG. 8 is a layout view illustrating the active layer of FIG. 4, the first gate layer of FIG. 5, and the second gate layer of FIG. 7.

FIG. 9 is a layout view illustrating a first conductive layer included in a pixel.

FIG. 10 is a layout view illustrating the active layer of FIG. 4, the first gate layer of FIG. 5, the second gate layer of FIG. 7, and the first conductive layer of FIG. 9.

FIG. 11 is a layout view illustrating a second conductive layer included in a pixel.

FIG. 12 is a layout view illustrating the active layer of FIG. 4, the first gate layer of FIG. 5, the second gate layer of FIG. 7, the first conductive layer of FIG. 9, and the second conductive layer of FIG. 11.

FIG. 13 is an enlarged plan view of area A of FIG. 8.

FIG. 14 is a cross-sectional view taken along line I-I′ of FIG. 13.

FIG. 15 is a cross-sectional view taken along line II-II′ of FIG. 13.

FIG. 16 is a layout view illustrating an active layer included in a pixel.

FIG. 17 is a layout diagram illustrating a first gate layer included in a pixel.

FIG. 18 is a layout diagram illustrating the active layer of FIG. 16 and the first gate layer of FIG. 17.

FIG. 19 is a layout view illustrating a second gate layer included in a pixel.

FIG. 20 is a layout view illustrating the active layer of FIG. 16, the first gate layer of FIG. 17, and the second gate layer of FIG. 19.

FIG. 21 is a layout view illustrating a first conductive layer included in a pixel.

FIG. 22 is a layout view illustrating the active layer of FIG. 16, the first gate layer of FIG. 17, the second gate layer of FIG. 19, and the first conductive layer of FIG. 21.

FIG. 23 is a layout view illustrating a second conductive layer included in a pixel.

FIG. 24 is a layout view illustrating the active layer of FIG. 16, the first gate layer of FIG. 17, the second gate layer of FIG. 19, the first conductive layer of FIG. 21, and the second conductive layer of FIG. 23.

FIG. 25 is an enlarged plan view of area B of FIG. 20.

FIG. 26 is a cross-sectional view taken along line III-III′ of FIG. 25.

FIG. 27 is a cross-sectional view taken along line IV-IV′ of FIG. 25.

### DETAILED DESCRIPTION OF THE EMBODIMENTS

Hereinafter, a display device according to embodiments of the present disclosure will be explained in detail with reference to the accompanying drawings. The same reference numerals are used for the same components in the drawings, and redundant descriptions of the same components will be omitted.

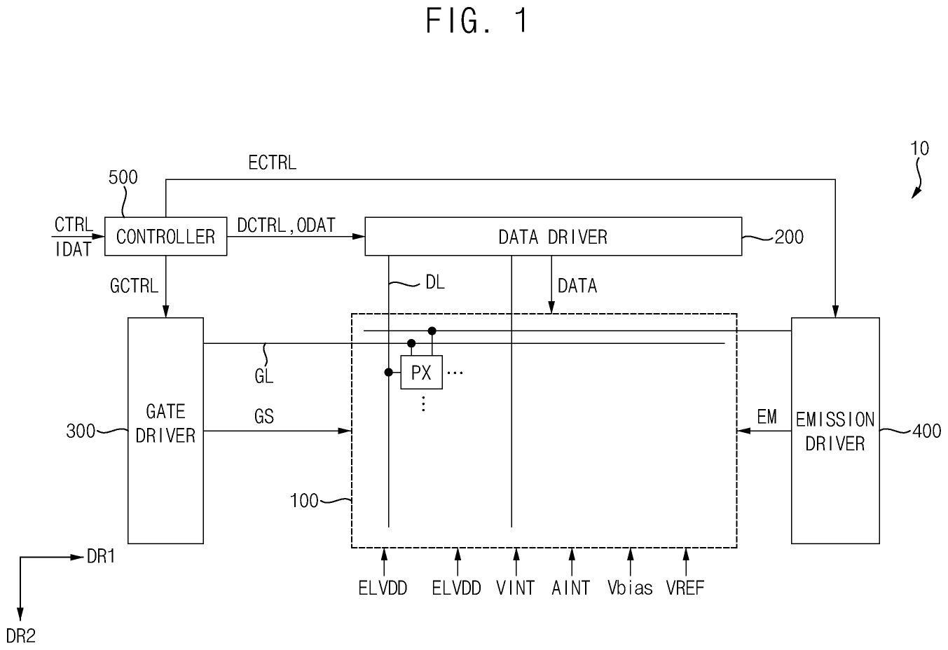

FIG. 1 is a block diagram illustrating a display device according to an embodiment of the present disclosure.

Referring to FIG. 1, a display device 10 may include a pixel portion 100, a data driver 200, a gate driver 300, an emission driver 400, and a controller 500.

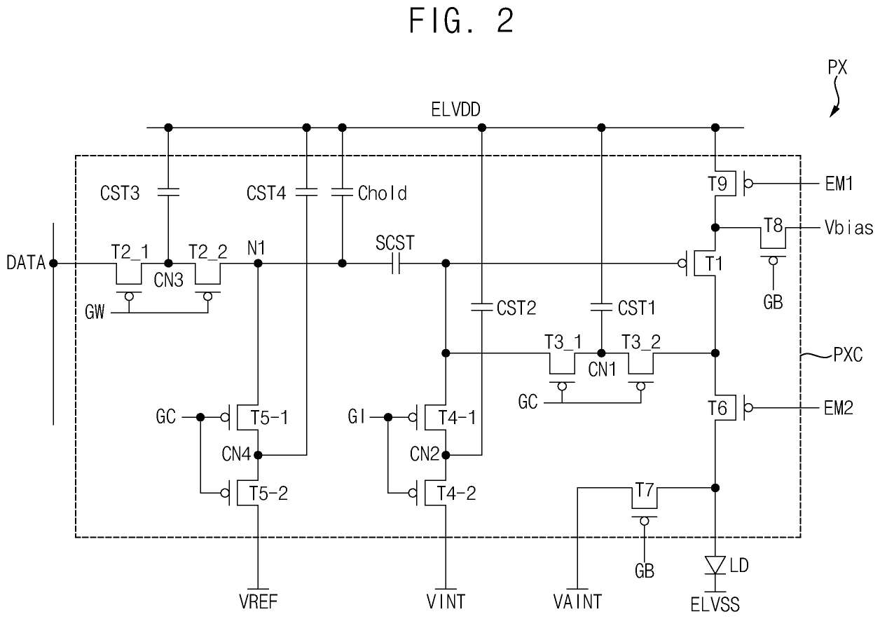

The pixel portion 100 may include a plurality of pixels PX. Each of the pixels PX may emit light having a preset color. The pixel portion 100 may have an RGBG pixel structure, and each of the pixels PX may emit red, green, or blue light. Each of the pixels PX may include a pixel circuit (e.g., a pixel circuit PXC of FIG. 2) and a light emitting diode (e.g., a light emitting diode LD of FIG. 2). Each of the pixels PX may be driven through the pixel circuit.

The data driver 200 may be implemented with one or more integrated circuits (ICs). In another embodiment, the data driver 200 may be mounted on a peripheral portion or may be integrated in the peripheral portion.

The data driver 200 may generate data voltages DATA based on an output image data ODAT and a data control signal DCTRL. For example, the data driver 200 may generate the data voltages DATA corresponding to the output image data ODAT and output the data voltages DATA in response to the data control signal DCTRL. The data driver 200 may output the data voltages DATA through data lines DL. For example, the data driver 200 may output the data voltages DATA to the pixels PX through the data line DL.

The output image data ODAT may be RGB data for an image displayed in the pixel portion 100, and the data control signal DCTRL may include an output data enable signal, a horizontal start signal, and a load signal.

The gate driver 300 may generate gate signals GS based on a gate control signal GCTRL. The gate signal GS may be a clock signal. The gate signal GS may include a turn-on voltage for turning on the transistor and a turn-off voltage for turning off the transistor. The gate driver 300 may sequentially output the gate signals GS through gate lines GL. For example, the gate driver 300 may output the gate signals GS to the pixels PX through the gate lines GL. The gate control signal GCTRL may include a vertical start signal, a clock signal, and the like. In an embodiment, the gate driver 300 may be mounted on the peripheral portion or may be integrated in the periphery portion. In another embodiment, the gate driver 300 may be implemented as one or more integrated circuits.

The emission driver 400 may generate light emitting driving signals EM based on a light emitting control signal ECTRL. The light emitting driving signals EM may be a clock signal and may include the turn-on voltage and the turn-off voltage. The emission driver 400 may sequentially output the light emitting driving signals EM to light emitting driving signal lines. The light emitting control signal ECTRL may include a vertical start signal and a clock signal. In an embodiment, the emission driver 400 may be mounted on the peripheral portion or may be integrated in the peripheral portion. In another embodiment, the emission driver 400 may be implemented as one or more integrated circuits.

The controller 500 (e.g., timing controller T-CON) may receive an input image data IDAT and a control signal CTRL from an external host processor (e.g., GPU). For example, the input image data IDAT may be RGB data including red image data, green image data, and blue image data. The controller 500 may generate the gate control signal GCTRL, the data control signal DCTRL, and the output image data ODAT based on the input image data IDAT and the control signal CTRL.

A first voltage ELVDD may be applied to the pixel portion 100. The first voltage ELVDD may be applied to the pixel portion 100 through a power line. A second voltage ELVSS (e.g., a low power supply voltage) may be applied to the pixel portion 100. The second voltage ELVSS may be applied to the pixel portion 100 through a common electrode. A transistor initialization voltage VINT and an anode initialization voltage VAINT may be applied to the pixel portion 100. A reference voltage VREF and a bias voltage Vbias may be applied to the pixel portion 100.

FIG. 2 is a circuit diagram for explaining an example of a pixel included in the display device of FIG. 1.

Referring to FIGS. 1 and 2, the pixel PX may be driven through the pixel circuit PXC. The pixel PX may include the pixel circuit PXC and a light emitting diode LD. The pixel circuit PXC may include a plurality of transistors and at least one capacitor.

In an embodiment, the pixel circuit PXC may include a driving transistor, a plurality of switching transistors, and a storage capacitor SCST.

For example, the pixel circuit PXC may include a first transistor T1 serving as the driving transistor, a plurality of transistors (e.g., a second transistor T2, a third transistor T3, a fourth transistor T4, a fifth transistor T5, a sixth transistor T6, a seventh transistor T7, an eighth transistor T8, and a ninth transistor T9), the storage capacitor SCST, a hold capacitor Chold, a first capacitor CST1, and a second capacitor CST2.

The first transistor T1 may include a gate terminal, a first terminal, and a second terminal. The first terminal of the first transistor T1 may receive the first voltage ELVDD. The second terminal of the first transistor T1 may be electrically connected to the light emitting diode LD through the sixth transistor T6. The first transistor T1 may generate a driving current. The first transistor T1 may transfer the driving current to the light emitting diode LD.

The second transistor T2 may receive a first gate signal GW through the gate line GL. For example, the first gate signal GW may be referred to as a write gate signal GW. The second transistor T2 may receive the data voltage DATA through the data line DL. The second transistor T2 may be connected to a first node N1. The data voltage DATA may be provided to the first node N1 while the second transistor T2 is turned on.

The second transistor T2 may be turned on or off in response to the first gate signal GW. For example, when the second transistor T2 is a PMOS transistor, the second transistor T2 may be turned off when the first gate signal GW has a positive voltage level and the second transistor T2 may be turned on when the first gate signal GW has a negative voltage level.

The second transistor T2 may have a dual-gate structure. For example, the second transistor T2 may include a first sub-transistor T2-1 and a second sub-transistor T2-2. The first sub-transistor T2-1 and the second sub-transistor T2-2 may be connected to each other through a third common node CN3. As the second transistor T2 has a dual-gate structure, reliability of the second transistor T2 may be improved.

The third transistor T3 may be connected to the storage capacitor SCST, the gate terminal of the first transistor T1 and the second terminal of the first transistor T1.

The third transistor T3 may receive a second gate signal GC. For example, the second gate signal GC may be referred to as a compensation control signal GC.

The third transistor T3 may be turned on or off in response to the second gate signal GC. For example, when the third transistor T3 is a PMOS transistor, the third transistor T3 is turned off when the second gate signal GC has a positive voltage level, and the third transistor T3 may be turned on when the second gate signal GC has a negative voltage level. During a period in which the third transistor T3 is turned on in response to the second gate signal GC, the third transistor T3 may diode-connect the first transistor T1. Accordingly, the third transistor T3 may compensate for the threshold voltage of the first transistor T1.

The third transistor T3 may have a dual-gate structure. For example, the third transistor T3 may include a first sub-transistor T3-1 and a second sub-transistor T3-2. The first sub-transistor T3-1 and the second sub-transistor T3-2 may be connected to each other through a first common node CN1. As the third transistor T3 has a dual-gate structure, reliability of the third transistor T3 may be improved.

The fourth transistor T4 may be connected to the storage capacitor SCST, the third transistor T3, and the gate terminal of the first transistor T1. In addition, the fourth transistor T4 may receive the transistor initialization voltage VINT.

The fourth transistor T4 may receive a third gate signal GI. For example, the third gate signal GI may be referred to as an initialization gate signal GI. The fourth transistor T4 may connect the first gate terminal of the first transistor T1 to the transistor initialization voltage VINT.

The fourth transistor T4 may be turned on or off in response to the third gate signal GI. For example, when the fourth transistor T4 is a PMOS transistor, the fourth transistor T4 may be turned off when the third gate signal GI has a positive voltage level, and the fourth transistor T4 may be turned on when the third gate signal GI has a negative voltage level.

During a period in which the fourth transistor T4 is turned on in response to the third gate signal GI, the gate terminal of the first transistor T1 may be electrically connected to the transistor initialization voltage VINT. Accordingly, the fourth transistor T4 may transmit the transistor initialization voltage VINT to the first gate terminal of the first transistor T1 in response to the third gate signal GI.

The fourth transistor T4 may have a dual-gate structure. The fourth transistor T4 may include a first sub-transistor T4-1 and a second sub-transistor T4-2. The first sub-transistor T4-1 and the second sub-transistor T4-2 may be connected to each other through a second common node CN2. As the fourth transistor T4 has a dual-gate structure, reliability of the fourth transistor T4 may be improved.

The fifth transistor T5 may receive the second gate signal GC. The fifth transistor T5 may receive the reference voltage VREF.

The fifth transistor T5 may be turned on or off in response to the second gate signal GC. For example, when the fifth transistor T5 is a PMOS transistor, the fifth transistor T5 may be turned off when the second gate signal GC has a positive voltage level, and the fifth transistor T5 may be turned on when the second gate signal GC has a negative voltage level. The fifth transistor T5 may be connected to the first node N1. During a period in which the fifth transistor T5 is turned on in response to the second gate signal GC, the reference voltage VREF may be provided to the first node N1.

The fifth transistor T5 may have a dual-gate structure. The fifth transistor T5 may include a first sub-transistor T5-1 and a second sub-transistor T5-2. The first sub-transistor T5-1 and the second sub-transistor T5-2 may be connected to each other through a fourth common node CN4. As the fifth transistor T5 has a dual-gate structure, reliability of the fifth transistor T5 may be improved.

The sixth transistor T6 may receive a second light emitting driving signal EM2. The sixth transistor T6 may be connected to the second terminal of the first transistor T1. The sixth transistor T6 may be connected to the light emitting diode LD. When the sixth transistor T6 is turned on in response to the second light emitting driving signal EM2, the sixth transistor T6 may provide the driving current to the light emitting diode LD. For example, the sixth transistor T6 may be referred to as a light emitting control transistor.

The seventh transistor T7 may receive a fourth gate signal GB. For example, the fourth gate signal GB may be referred to as a bias gate signal GB. The seventh transistor T7 may be connected to the light emitting diode LD. The seventh transistor T7 may receive the anode initialization voltage VAINT. When the seventh transistor T7 is turned on in response to the fourth gate signal GB, the seventh transistor T7 may provide the anode initialization voltage VAINT to the light emitting diode LD. Accordingly, the seventh transistor T7 may initialize the light emitting diode LD with the anode initialization voltage VAINT. For example, the seventh transistor T7 may be referred to as an anode initialization transistor.

The eighth transistor T8 may receive the fourth gate signal GB. The eighth transistor T8 may receive a bias voltage Vbias. When the eighth transistor T8 is turned on in response to the fourth gate signal GB, the eighth transistor T8 may provide the bias voltage Vbias to the first terminal of the first transistor T1.

The ninth transistor T9 may receive a first light emitting driving signal EM1. The ninth transistor T9 may be connected to the first terminal of the first transistor T1. The ninth transistor T9 may receive the first voltage ELVDD through the power line. When the ninth transistor T9 is turned on in response to the first light emitting driving signal EM1, the ninth transistor T9 may provide the first voltage ELVDD to the first transistor T1. For example, the ninth transistor T9 may be referred to as a light emitting control transistor.

The storage capacitor SCST may include a first terminal and a second terminal. The first terminal of the storage capacitor SCST may be connected to the first transistor T1, and the second terminal of the storage capacitor SCST may be connected to the first node N1. The storage capacitor SCST may maintain a voltage level of the gate terminal of the first transistor T1 during an inactive period of the first gate signal GW.

The hold capacitor Chold may include a first terminal and a second terminal. The first terminal of the hold capacitor Chold may be connected to the storage capacitor SCST and the first node N1, and the second terminal of the hold capacitor Chold may receive the first voltage ELVDD.

The first capacitor CST1 may include a first terminal and a second terminal. The first terminal of the first capacitor CST1 may be connected to the first common node CN1, and the second terminal of the first capacitor CST1 may receive the first voltage ELVDD. The first capacitor CST1 may prevent the voltage of the first common node CN1 from increasing and maintain the voltage level of the first common node CN1.

The second capacitor CST2 may include a first terminal and a second terminal. The first terminal of the second capacitor CST2 may be connected to the second common node CN2, and the second terminal of the second capacitor CST2 may receive the first voltage ELVDD. The second capacitor CST2 may prevent the voltage of the second common node CN2 from increasing and maintain the voltage level of the second common node CN2.

The third capacitor CST3 may include a first terminal and a second terminal. The first terminal of the third capacitor CST3 may be connected to the third common node CN3, and the second terminal of the third capacitor CST3 may receive the first voltage ELVDD. The third capacitor CST3 may prevent the voltage of the third common node CN3 from increasing and maintain the voltage level of the third common node CN3.

The fourth capacitor CST4 may include a first terminal and a second terminal. The first terminal of the fourth capacitor CST4 may be connected to the fourth common node CN4, and the second terminal of the fourth capacitor CST4 may receive the first voltage ELVDD. The fourth capacitor CST4 may prevent the voltage of the fourth common node CN4 from increasing and maintain the voltage level of the fourth common node CN4.

The light emitting diode LD may include the first terminal (e.g., an anode terminal) and a second terminal (e.g., a cathode terminal). The first terminal of the light emitting diode LD may be connected to the sixth transistor T6 to receive the driving current, and the second terminal may receive the second voltage ELVSS. The light emitting diode LD may generate light having luminance corresponding to the driving current.

In an embodiment, the display device 10 may further include the first capacitor CST1 and the second capacitor CST2 in addition to the storage capacitor SCST and the hold capacitor Chold. The voltage of the first common node CN1 may be maintained relatively constant due to the first capacitor CST1. Similarly, the voltage of the second common node CN2 may be maintained relatively constant due to the second capacitor CST2. That is, the first capacitor CST1 can prevent leakage current of the third transistor T3, and the second capacitor CST2 can prevent leakage current of the fourth transistor T4. Accordingly, the first capacitor CST1 and the second capacitor CST2 may maintain a constant voltage of the storage capacitor SCST. Accordingly, a low-frequency characteristic of the display device 10 can be improved.

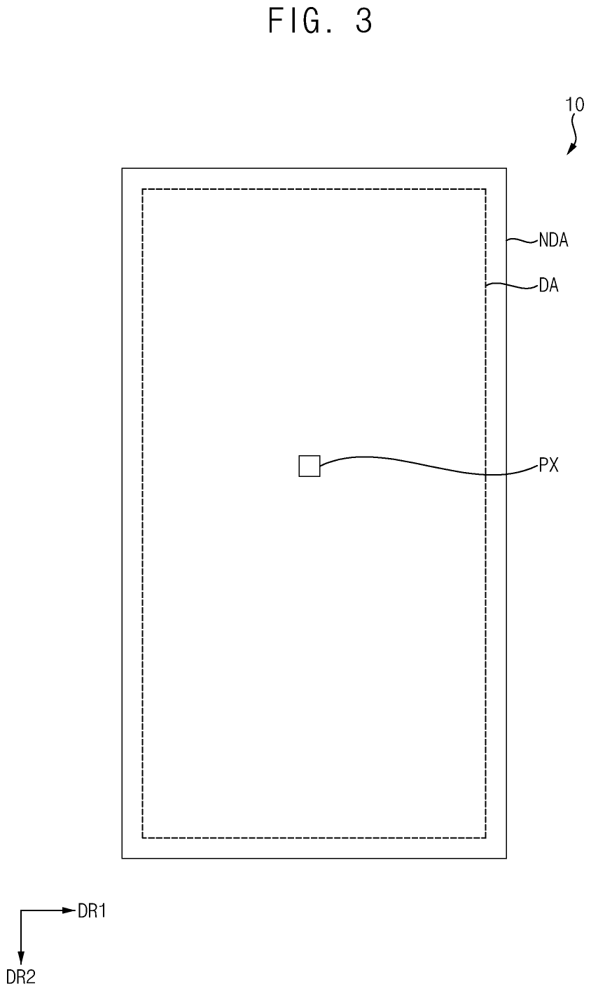

FIG. 3 is a plan view illustrating a display device according to an embodiment of the present disclosure.

Referring to FIG. 3, the display device 10 may include a display area DA and a non-display area NDA. The display area DA may display images. The plurality of pixels PX that emit light and lines that transmit driving signals to the pixels PX may be disposed in the display area DA. The lines may transmit gate signals, data signals, or voltages.

The non-display area NDA may be an area that does not display images. Lines for driving the pixels PX and drivers may be disposed in the non-display area NDA. For example, a gate driver, a light emitting driver, a pad, and a driving chip may be disposed in the non-display area NDA. The non-display area NDA may be disposed adjacent to the display area DA and may surround at least one side of the display area DA. However, embodiments according to the present disclosure are not limited thereto, and images may be displayed in the non-display area NDA.

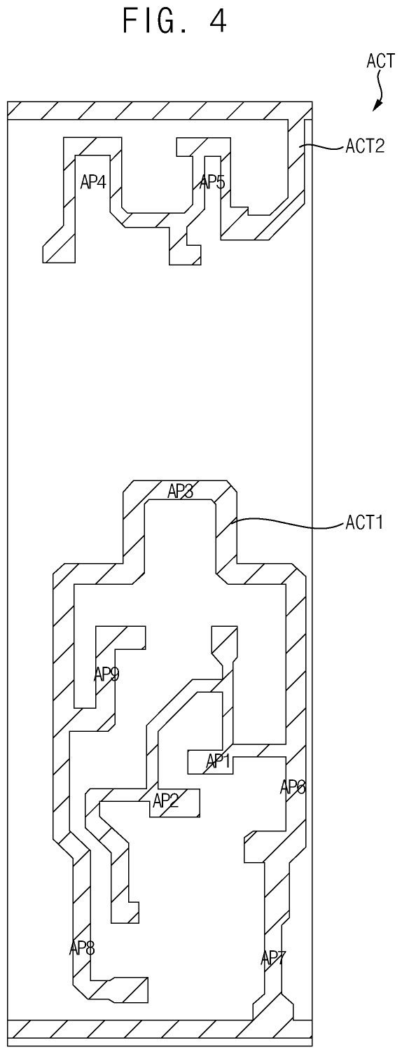

FIGS. 4 to 12 are layout views for explaining an example of a pixel included in the display device of FIG. 3.

FIG. 4 is a layout view illustrating an active layer included in a pixel.

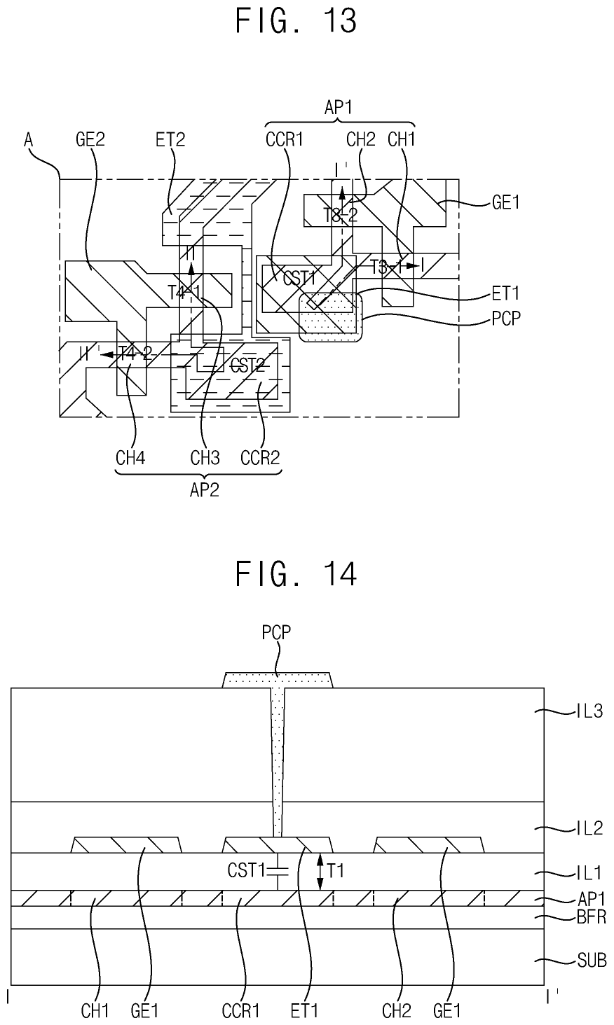

Referring to FIG. 4, a substrate (e.g., the substrate SUB of FIG. 14) may have a structure in which at least one polymer film and at least one barrier layer are alternately stacked. For example, the polymer film may be formed using an organic material such as polyimide, and the barrier layer may be formed using an inorganic material.

A buffer layer (e.g., a buffer layer BFR of FIG. 14) may be disposed on the substrate SUB. The buffer layer may prevent diffusion of metal atoms or impurities from the substrate into the active layer ACT.

The active layer ACT may be disposed on the buffer layer. The active layer ACT may include a first active layer ACT1 and a second active layer ACT2. The first active layer ACT1 and the second active layer ACT2 may be spaced apart from each other. Each of the first active layer ACT1 and the second active layer ACT2 may include a semiconductive material. Each of the first active layer ACT1 and the second active layer ACT2 may include a plurality of active patterns AP1, AP2, AP3, AP4, AP5, AP6, AP7, AP8, and AP9. For example, the first active layer ACT1 may include a first active pattern AP1, a second active pattern AP2, a third active pattern AP3, a sixth active pattern AP6, and a seventh active pattern AP7, an eighth active pattern AP8, and a ninth active pattern AP9. The second active layer ACT2 may include a fourth active pattern AP4 and a fifth active pattern AP5.

In an embodiment, the active patterns AP1, AP2, AP3, AP6, AP7, AP8, and AP9 included in the first active layer ACT1 may constitute the first active layer ACT1 which is connected to each other. The active patterns AP1, AP2, AP3, AP6, AP7, AP8, and AP9 may be integrally formed. The active patterns AP4 and AP5 included in the second active layer ACT2 may constitute the second active layer ACT2 which is connected to each other. The active patterns AP4 and AP5 may be integrally formed.

A first insulating layer (e.g., a first insulating layer IL1 of FIG. 14) may be disposed on the buffer layer. The first insulating layer may cover the active layer ACT. For example, the first insulating layer may include an inorganic material.

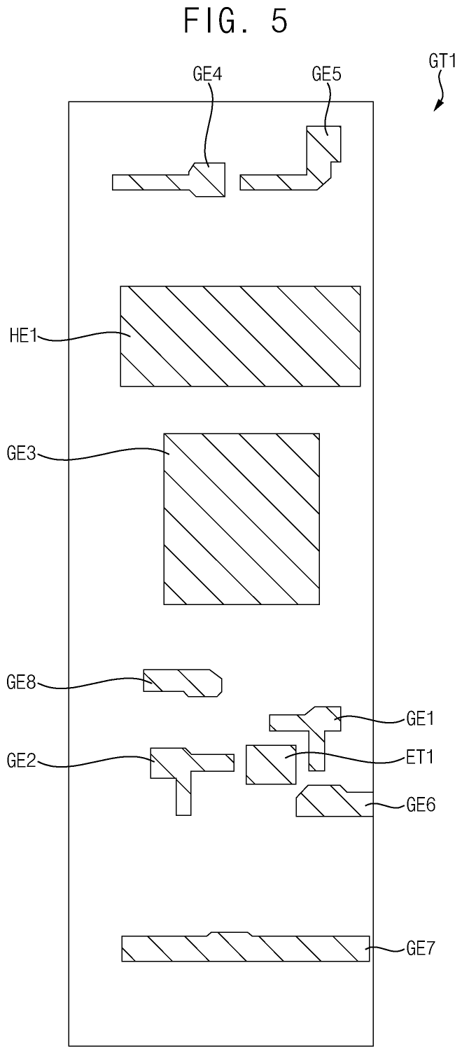

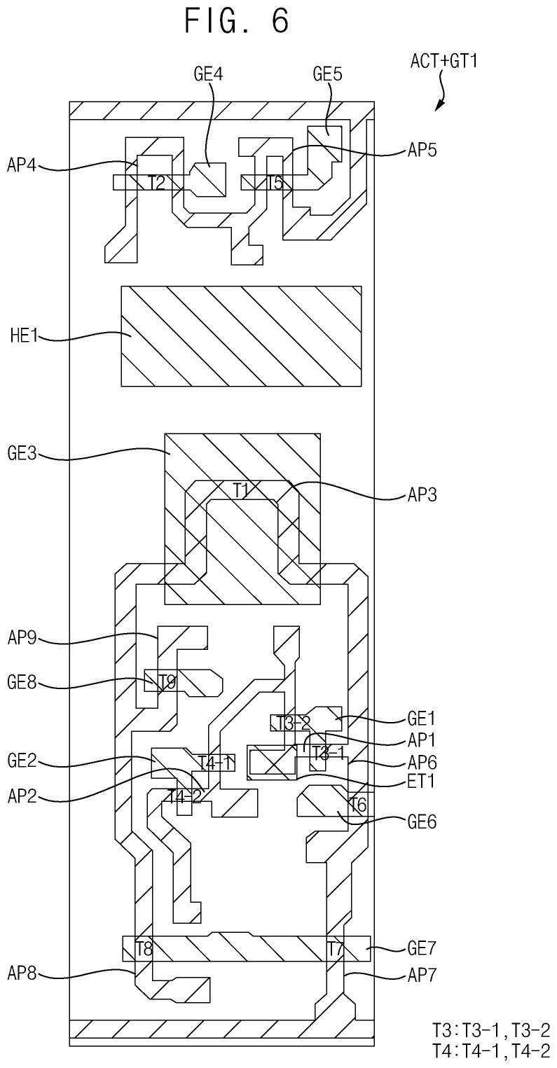

FIG. 5 is a layout view illustrating a first gate layer included in a pixel. FIG. 6 is a layout view illustrating the active layer of FIG. 4 and the first gate layer of FIG. 5.

Further referring to FIGS. 5 and 6, a first gate layer GT1 may be disposed on the first insulating layer IL1. The first gate layer GT1 may include a conductive material. The first gate layer GT1 may include a first gate electrode GE1, a second gate electrode GE2, a third gate electrode GE3, a fourth gate electrode GE4, a fifth gate electrode GE5, a sixth gate electrode GE6, a seventh gate electrode GE7, an eighth gate electrode GE8, a first hold electrode HE1, and a first electrode ET1. The first gate electrode GE1, the second gate electrode GE2, the third gate electrode GE3, the fourth gate electrode GE4, the fifth gate electrode GE5, and the sixth gate electrode GE6, the seventh gate electrode GE7, the eighth gate electrode GE8, the first hold electrode HE1, and the first electrode ET1 may be spaced apart from each other.

The first gate electrode GE1 may be disposed on the first active pattern AP1. The first gate electrode GE1 may partially overlap the first active pattern AP1. The first gate electrode GE1 and the first active pattern AP1 may constitute the third transistor T3. The third transistor T3 may be a dual transistor.

The second gate electrode GE2 may be disposed on the second active pattern AP2. The second gate electrode GE2 may be spaced apart from the first gate electrode GE1. The second gate electrode GE2 may partially overlap the second active pattern AP2. The second gate electrode GE2 and the second active pattern AP2 may constitute the fourth transistor T4. The fourth transistor T4 may be a dual transistor.

The third gate electrode GE3 may be disposed on the third active pattern AP3. The third gate electrode GE3 may overlap the third active pattern AP3. The third gate electrode GE3 and the third active pattern AP3 may constitute the first transistor T1.

The fourth gate electrode GE4 may be disposed on the fourth active pattern AP4. The fourth gate electrode GE4 may partially overlap the fourth active pattern AP4. The fourth gate electrode GE4 and the fourth active pattern AP4 may constitute the second transistor T2. The second transistor T2 may be a dual transistor.

The fifth gate electrode GE5 may be disposed on the fifth active pattern AP5. The fifth gate electrode GE5 may partially overlap the fifth active pattern AP5. The fifth gate electrode GE5 and the fifth active pattern AP5 may configure the fifth transistor T5. The fifth transistor T5 may be a dual transistor.

The sixth gate electrode GE6 may be disposed on the sixth active pattern AP6. The sixth gate electrode GE6 may partially overlap the sixth active pattern AP6. The sixth gate electrode GE6 and the sixth active pattern AP6 may constitute the sixth transistor T6.

The seventh gate electrode GE7 may be disposed on the seventh active pattern AP7 and the eighth active pattern AP8. The seventh gate electrode GE7 may partially overlap the seventh active pattern AP7 and the eighth active pattern AP8. The seventh gate electrode GE7 and the seventh active pattern AP7 may constitute the seventh transistor T7, and the seventh gate electrode GE7 and the eighth active pattern AP8 may constitute the eighth transistor T8.

The eighth gate electrode GE8 may be disposed on the ninth active pattern AP9. The eighth gate electrode GE8 may partially overlap the ninth active pattern AP9. The eighth gate electrode GE8 and the ninth active pattern AP9 may constitute the ninth transistor T9.

The first hold electrode HE1 may be spaced apart from the first active layer ACT1 and the second active layer ACT2.

In an embodiment, the first electrode ET1 may be disposed on the first active pattern AP1. The first electrode ET1 may overlap the first active pattern AP1. The first electrode ET1 may be spaced apart from the first gate electrode GE1 and the second gate electrode GE2 in the plan view.

A second insulating layer (e.g., the second insulating layer IL2 of FIG. 14) may be disposed on the first insulating layer. The second insulating layer may cover the first gate layer GT1. For example, the second insulating layer may include an inorganic material.

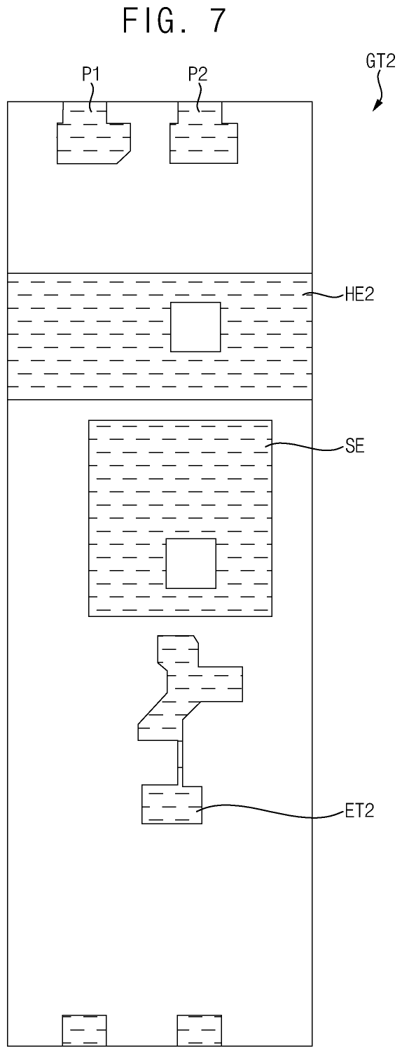

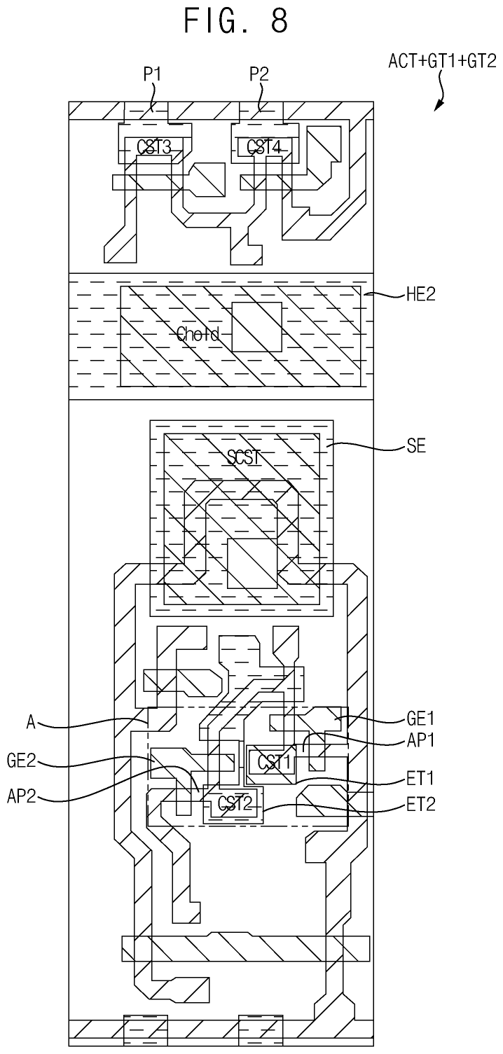

FIG. 7 is a layout view illustrating a second gate layer included in a pixel. FIG. 8 is a layout view illustrating the active layer of FIG. 4, the first gate layer of FIG. 5, and the second gate layer of FIG. 7.

Further referring to FIGS. 7 and 8, a second gate layer GT2 may be disposed on the second insulating layer. The second gate layer GT2 may include a conductive material. The second gate layer GT2 may include a second electrode ET2, a storage electrode SE, a second hold electrode HE2, and stabilization electrodes P1 and P2.

In an embodiment, the second electrode ET2 may be disposed on the second active pattern AP2. The second electrode ET2 may overlap the second active pattern AP2. The second electrode ET2 may be spaced apart from the first electrode ET1 in the plan view.

The storage electrode SE may overlap the third gate electrode GE3. The storage electrode SE and the third gate electrode GE3 may constitute the storage capacitor SCST.

The second hold electrode HE2 may overlap the first hold electrode HE1. The second hold electrode HE2 and the first hold electrode HE1 may constitute the hold capacitor Chold.

The stabilization electrodes P1 and P2 may be disposed on the second active layer ACT2. The stabilizing electrodes P1 and P2 may include two electrodes. Specifically, the stabilization electrodes P1 and P2 may overlap the fourth and fifth active patterns AP4 and AP5, respectively. In addition, the stabilization electrodes P1 and P2 and the second active layer ACT2 may constitute capacitors. That is, the stabilization electrodes P1 and P2 and the fourth and fifth active patterns AP4 and AP5 may constitute the third capacitor CST3 and the fourth capacitor CST4, respectively.

For example, the stabilization electrodes P1 and P2 may include a first stabilization electrode P1 and a second stabilization electrode P2. The first stabilization electrode P1 and the fourth active pattern AP4 may constitute the third capacitor CST3. The second stabilization electrode P2 and the fifth active pattern AP5 may constitute the fourth capacitor CST4. However, the present disclosure is not limited thereto. In an embodiment, the capacitance of the third capacitor CST3 may be different from the capacitance of the fourth capacitor CST4. For example, the capacitance of the third capacitor CST3 may be greater than the capacitance of the fourth capacitor CST4. For another example, the capacitance of the third capacitor CST3 may be smaller than the capacitance of the fourth capacitor CST4.

In order to make the capacitance of the third capacitor CST3 and the capacitance of the fourth capacitor CST4 different from each other, one of the stabilization electrodes P1 and P2 may be disposed in a layer other than the second gate layer GT2. For example, the first stabilization electrode P1 may be disposed on the same layer as the first gate layer GT1 and the second stabilization electrode P2 may be disposed on the same layer as the second gate layer GT2. In this case, the capacitance of the third capacitor CST3 may be greater than the capacitance of the fourth capacitor CST4. However, the present disclosure is not limited thereto, and in another embodiment, the first stabilization electrode P1 may be disposed in the second gate layer GT2, and the second stabilization electrode P2 may be disposed in the first gate layer GT1. In this case, the capacitance of the third capacitor CST3 may be smaller than the capacitance of the fourth capacitor CST4.

A third insulating layer (e.g., the third insulating layer IL3 of FIG. 14) may be disposed on the second insulating layer. The third insulating layer may cover the second gate layer GT2. For example, the third insulating layer may include an inorganic material.

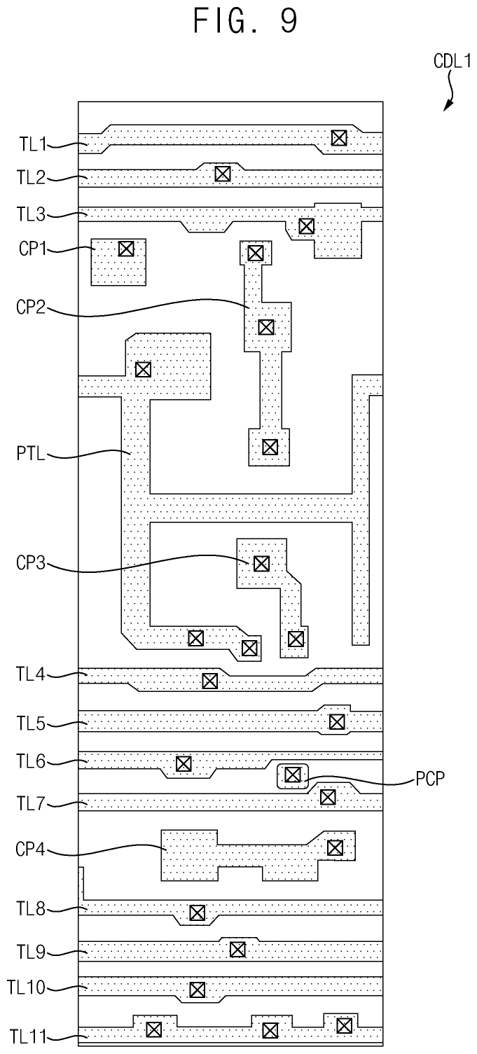

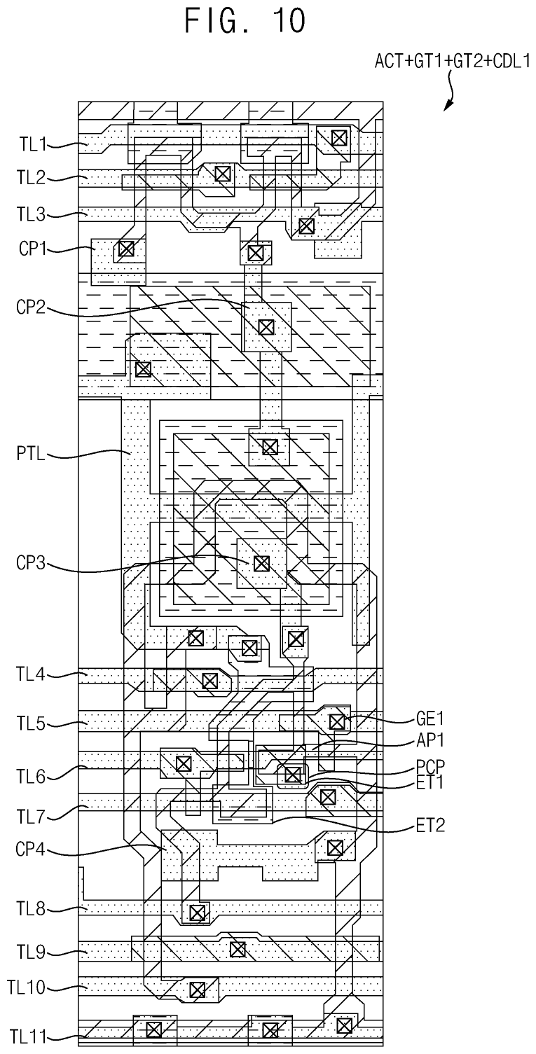

FIG. 9 is a layout view illustrating a first conductive layer included in a pixel. FIG. 10 is a layout view illustrating the active layer of FIG. 4, the first gate layer of FIG. 5, the second gate layer of FIG. 7, and the first conductive layer of FIG. 9.

Further referring to FIGS. 9 and 10, the first conductive layer CDL1 may be disposed on the third insulating layer. The first conductive layer CDL1 may include a conductive material. The first conductive layer CDL1 may include first, second, third, fourth, fifth, sixth, seventh, eighth, ninth, tenth, and eleventh transfer lines TL1, TL2, TL3, TL4, TL5, TL6, TL7, TL8, TL9, TL10, and TL11, first, second, third, and fourth connection patterns CP1, CP2, CP3, and CP4, a power transfer line PTL, and a power connection pattern PCP. The first, second, third, fourth, fifth, sixth, seventh, eighth, ninth, tenth, and eleventh transfer lines TL1, TL2, TL3, TL4, TL5, TL6, TL7, TL8, TL9, TL10, and TL11, the first, second, third, and fourth connection patterns CP1, CP2, CP3, and CP4, the power transfer line PTL, and the power connection pattern PCP may be spaced apart from each other.

The first transfer line TL1 may transfer the second gate signal GC. The first transmission line TL1 may be connected to the fifth gate electrode GE5. Accordingly, the first transmission line TL1 may transfer the second gate signal GC to the fifth transistor T5.

The second transfer line TL2 may transfer the first gate signal GW. The second transfer line TL2 may be connected to the fourth gate electrode GE4. Accordingly, the second transfer line TL2 may transfer the first gate signal GW to the second transistor T2.

The third transfer line TL3 may transfer the reference voltage VREF. The third transfer line TL3 may be connected to the fifth active pattern AP5. Accordingly, the third transfer line TL3 may transfer the reference voltage VREF to the fifth transistor T5.

The fourth transfer line TL4 may transfer the first light emitting driving signal EM1. The fourth transfer line TL4 may be connected to the eighth gate electrode GE8. Accordingly, the fourth transfer line TL4 may transfer the first light emitting driving signal EM1 to the ninth transistor T9.

The fifth transmission line TL5 may transfer the second gate signal GC. The fifth transfer wire TL5 may be connected to the first gate electrode GE1. Accordingly, the fifth transmission line TL5 may transfer the second gate signal GC to the third transistor T3.

The sixth transfer line TL6 may transfer the third gate signal GI. The sixth transfer line TL6 may be connected to the second gate electrode GE2. Accordingly, the sixth transfer line TL6 may transfer the third gate signal GI to the fourth transistor T4.

The seventh transfer line TL7 may transfer the second light emitting driving signal EM2. The seventh transfer line TL7 may be connected to the sixth gate electrode GE6. Accordingly, the seventh transfer line TL7 may transfer the second light emitting driving signal EM2 to the sixth transistor T6.

The eighth transfer line TL8 may transfer the transistor initialization voltage VINT. The eighth transfer line TL8 may be connected to the second active pattern AP2. The eighth transfer line TL8 may transfer the transistor initialization voltage VINT to the fourth transistor T4.

The ninth transfer line TL9 may transfer the fourth gate signal GB. The ninth transfer line TL9 may be connected to the seventh gate electrode GE7. Accordingly, the ninth transfer line TL9 may transfer the fourth gate signal GB to the seventh transistor T7 and the eighth transistor T8.

The tenth transfer line TL10 may transfer the bias voltage Vbias. The tenth transfer line TL10 may be connected to the eighth active pattern AP8. Accordingly, the tenth transfer line TL10 may transfer the bias voltage Vbias to the eighth transistor T8.

The eleventh transfer line TL11 may transfer the anode initialization voltage VAINT. The eleventh transfer line TL11 may be connected to the stabilization electrodes P1 and P2 and the seventh active pattern AP7. Accordingly, the eleventh transfer line TL11 may transfer the anode initialization voltage VAINT to the seventh transistor T7.

The first connection pattern CP1 may be connected to the fourth active pattern AP4. The second connection pattern CP2 may be connected to the active layer ACT (e.g., the first node N1 of FIG. 2) between the fourth active pattern AP4 and the fifth active pattern AP5, the first hold electrode HE1, and the storage electrode SE. The third connection pattern CP3 may be connected to the third gate electrode GE3 and the active layer ACT between the first and second active patterns AP1 and AP2. The fourth connection pattern CP4 may be connected to the active layer ACT between the sixth active pattern AP6 and the seventh active pattern AP7.

In an embodiment, the power transfer line PTL may be connected to the second hold electrode HE2, the ninth active pattern AP9, and the second electrode ET2. The power connection pattern PCP may be connected to the first electrode ET1.

A fourth insulating layer may be disposed on the third insulating layer. The fourth insulating layer may cover the first conductive layer CDL1. For example, the fourth insulating layer may include an inorganic material.

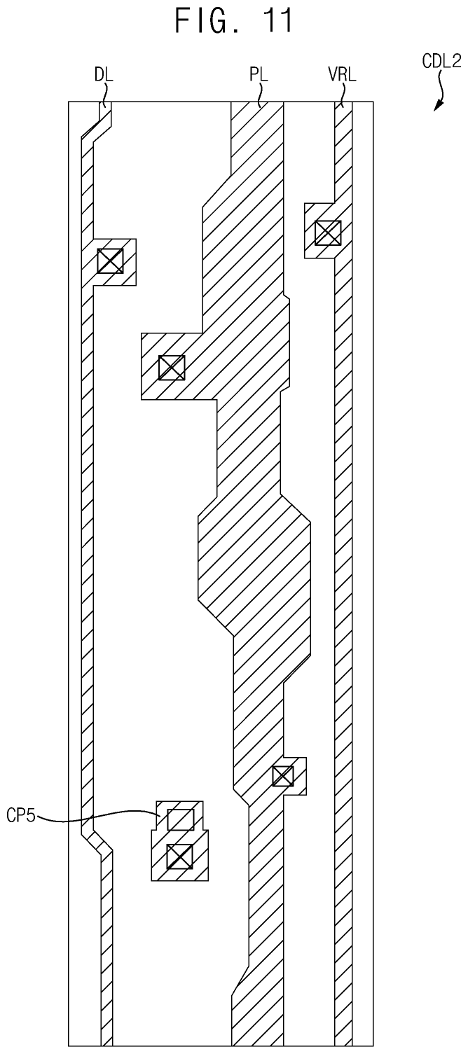

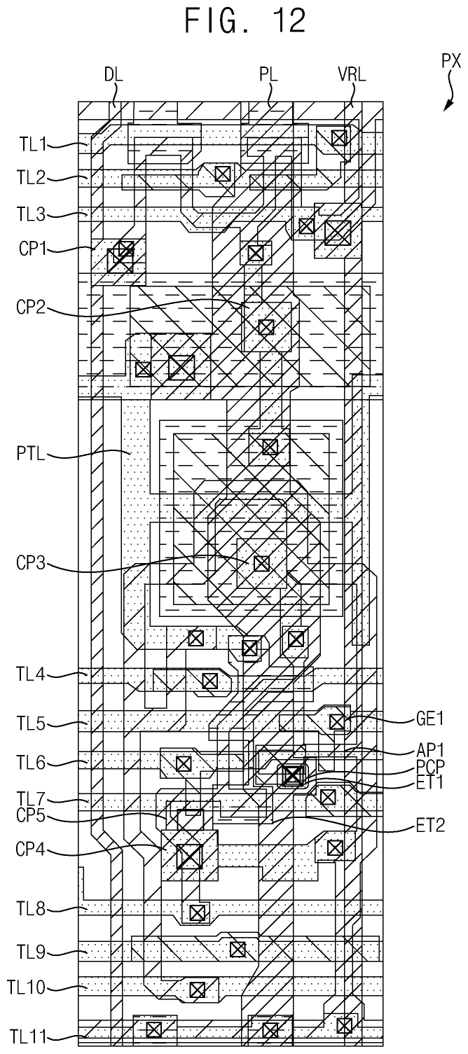

FIG. 11 is a layout view illustrating a second conductive layer included in a pixel. FIG. 12 is a layout view illustrating the active layer of FIG. 4, the first gate layer of FIG. 5, the second gate layer of FIG. 7, the first conductive layer of FIG. 9, and the second conductive layer of FIG. 11. For example, FIG. 12 may be a layout view illustrating the pixels PX.

Further referring to FIGS. 11 and 12, a second conductive layer CDL2 may be disposed on the fourth insulating layer. The second conductive layer CDL2 may include a conductive material. The second conductive layer CDL2 may include a data line DL, a power line PL, a reference voltage line VRL, and a fifth connection pattern CP5. The data line DL, the power line PL, the reference voltage line VRL, and the fifth connection pattern CP5 may be spaced apart from each other.

The data line DL may transfer the data voltage DATA. The data line DL may be connected to the first connection pattern CP1. The data line DL may transfer the data voltage DATA to the fourth active pattern AP4 through the first connection pattern CP1.

The power line PL may transfer the first voltage ELVDD. The power line PL may be connected to the power transfer line PTL and the power connection pattern PCP. That is, the power line PL may be connected to the second electrode ET2 through the power transfer line PTL and connected to the first electrode ET1 through the power connection pattern PCP. The power line PL may transfer the first voltage ELVDD to the second hold electrode HE2, the ninth active pattern AP9, the first electrode ET1, and the second electrode ET2 through the power transfer line PTL and the power connection pattern PCP.

The reference voltage line VRL may transfer the reference voltage VREF. The reference voltage line VRL may be connected to the third transfer line TL3. The reference voltage line VRL may transfer the reference voltage VREF to the fifth active pattern AP5 through the third transfer line TL3.

The fifth connection pattern CP5 may be connected to the fourth connection pattern CP4. The fifth connection pattern CP5 may be connected to an anode electrode on the second conductive layer CDL2. For example, the anode electrode may correspond to the first terminal of the light emitting diode LD of FIG. 2. The anode electrode may be electrically connected to the sixth active pattern AP6 and the seventh active pattern AP7 through the fifth connection pattern CP5 and the fourth connection pattern CP4.

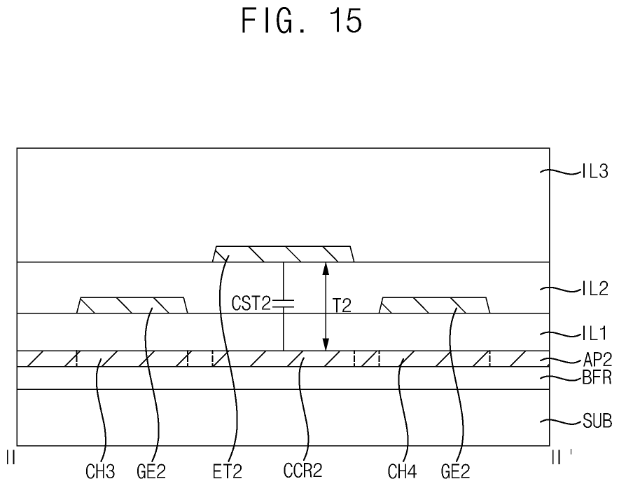

FIG. 13 is an enlarged plan view of area A of FIG. 8. FIG. 14 is a cross-sectional view taken along line I-I′ of FIG. 13. FIG. 15 is a cross-sectional view taken along line II-II′ of FIG. 13.

For example, only the first electrode ET1, the second electrode ET2, the first gate electrode GE1, the second gate electrode GE2, the first active pattern AP1, and the second active pattern AP2 of FIG. 8 and the power connection pattern PCP of FIG. 9 may be shown in FIG. 13.

Referring to FIGS. 2 and 13, the first active pattern AP1 may include a first channel region CH1, a second channel region CH2, and a first common conductive region CCR1. The first channel region CH1 and the second channel region CH2 may be spaced apart from each other. The first common conductive region CCR1 may be positioned between the first channel region CH1 and the second channel region CH2.

The third transistor T3 may include a first sub-transistor T3-1 and a second sub-transistor T3-2. The first sub-transistor T3-1 may include the first channel region CH1 and the first gate electrode GE1. The second sub-transistor T3-2 may include the second channel region CH2 and the first gate electrode GE1. That is, the first gate electrode GE1 may partially overlap the first active pattern AP1. For example, the first gate electrode GE1 may overlap each of the first channel region CH1 and the second channel region CH2. The first sub-transistor T3-1 and the second sub-transistor T3-2 may be serially connected to each other.

The first common conductive region CCR1 may overlap the first electrode ET1. The first common conductive region CCR1 may constitute the first capacitor CST1 (e.g., the first capacitor CST1 of FIG. 2) together with the first electrode ET1.

The second active pattern AP2 may be spaced apart from the first active pattern AP1. The second active pattern AP2 may include a third channel region CH3, a fourth channel region CH4, and a second common conductive region CCR2. The third channel region CH3 and the fourth channel region CH4 may be spaced apart from each other. The second common conductive region CCR2 may be positioned between the third channel region CH3 and the fourth channel region CH4.

The fourth transistor T4 may include a first sub-transistor T4-1 and a second sub-transistor T4-2. The first sub-transistor T4-1 may include the third channel region CH3 and the second gate electrode GE2. The second sub-transistor T4-2 may include the fourth channel region CH4 and the second gate electrode GE2. That is, the second gate electrode GE2 may partially overlap the second active pattern AP2. For example, the second gate electrode GE2 may overlap each of the third and fourth channel regions CH3 and CH4. The first sub-transistor T4-1 and the second sub-transistor T4-2 may be serially connected to each other.

The second common conductive region CCR2 may overlap the second electrode ET2. The second common conductive region CCR2 may constitute the second capacitor CST2 (e.g., the second capacitor CST2 of FIG. 2) together with the second electrode ET2.

Referring to FIGS. 14 and 15, the first capacitor CST1 may include the first electrode ET1 and the first common conductive region CCR1 of the first active pattern AP1 and the second capacitor CST2 may include the second electrode ET2 and the second common conductive region CCR2 of the second active pattern AP2. The first electrode ET1 and the second electrode ET2 may be disposed on different layers, and the second electrode ET2 may be disposed in a layer higher than the first electrode ET1. Therefore, a distance T1 between the first active pattern AP1 and the first electrode ET1 may be shorter than a distance T2 between the second active pattern AP2 and the second electrode ET2. Therefore, the capacitance of the first capacitor CST1 may be greater than the capacitance of the second capacitor CST2.

In an embodiment, the display device 10 may further include the first capacitor CST1 and the second capacitor CST2 in addition to the storage capacitor SCST and the hold capacitor Chold. Because the distance T1 between the first active pattern AP1 and the first electrode ET1 is shorter than the distance T2 between the second active pattern AP2 and the second electrode ET2, the capacitance of the first capacitor CST1 may be greater than the capacitance of the second capacitor CST2. The voltage of the storage capacitor SCST may be relatively more influenced by the first capacitor CST1 than by the second capacitor CST2. Therefore, by making the capacitance of the first capacitor CST1 greater than the capacitance of the second capacitor CST2, the leakage current of the third transistor T3 can be maintained less than the leakage current of the fourth transistor T4. As a result, the voltage of the storage capacitor SCST may be maintained constant, and a low frequency characteristic of the display device 10 can be improved.

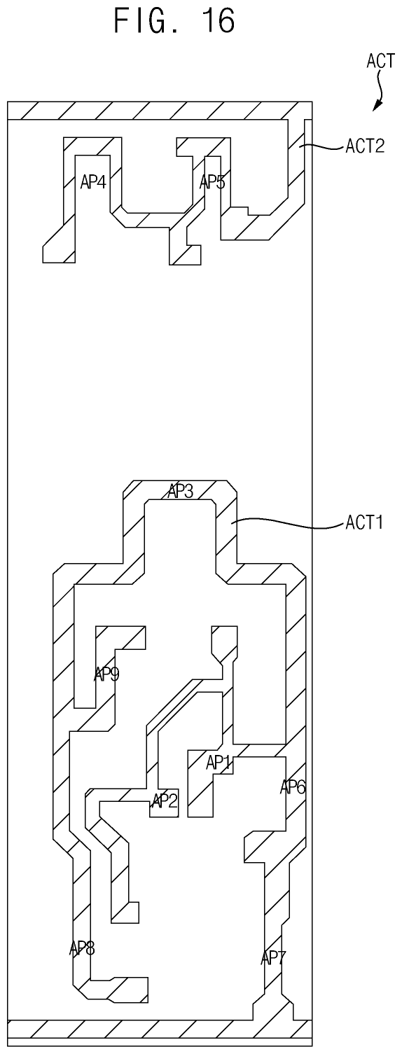

FIGS. 16 to 24 are layout views for explaining an example of a pixel included in the display device of FIG. 3.

Among a pixel PX′ described with reference to FIGS. 16 to 24, a description of the same configuration as the pixel PX described with reference to FIGS. 4 to 15 may be omitted or simplified.

FIG. 16 is a layout view illustrating an active layer included in a pixel.

Referring to FIG. 16, a buffer layer may be disposed on a substrate. An active layer ACT may be disposed on the buffer layer. The active layer ACT may include a first active layer ACT1 and a second active layer ACT2. The first active layer ACT1 and the second active layer ACT2 may be spaced apart from each other.

Each of the first active layer ACT1 and the second active layer ACT2 may include a semiconductive material. Each of the first active layer ACT1 and the second active layer ACT2 may include a plurality of active patterns AP1, AP2, AP3, AP4, AP5, AP6, AP7, AP8, and AP9. For example, the first active layer ACT1 may include a first active pattern AP1, a second active pattern AP2, a third active pattern AP3, a sixth active pattern AP6, a seventh active pattern AP7, an eighth active pattern AP8, and a ninth active pattern AP9. The second active layer ACT2 may include a fourth active pattern AP4 and a fifth active pattern AP5.

In an embodiment, the active patterns AP1, AP2, AP3, AP6, AP7, AP8, and AP9 included in the first active layer ACT1 may constitute the first active layer ACT1 which is connected to each other. The active patterns AP1, AP2, AP3, AP6, AP7, AP8, and AP9 may be integrally formed. The active patterns AP4 and AP5 included in the second active layer ACT2 may constitute the second active layer ACT2 which is connected to each other. The active patterns AP4 and AP5 may be integrally formed.

A first insulating layer (e.g., the first insulating layer IL1 of FIG. 14) may be disposed on the buffer layer. The first insulating layer may cover the active layer ACT.

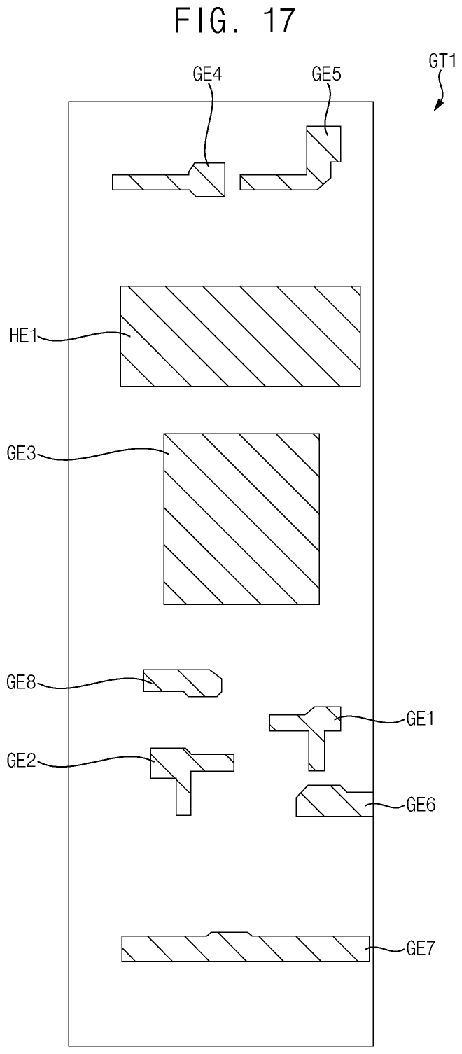

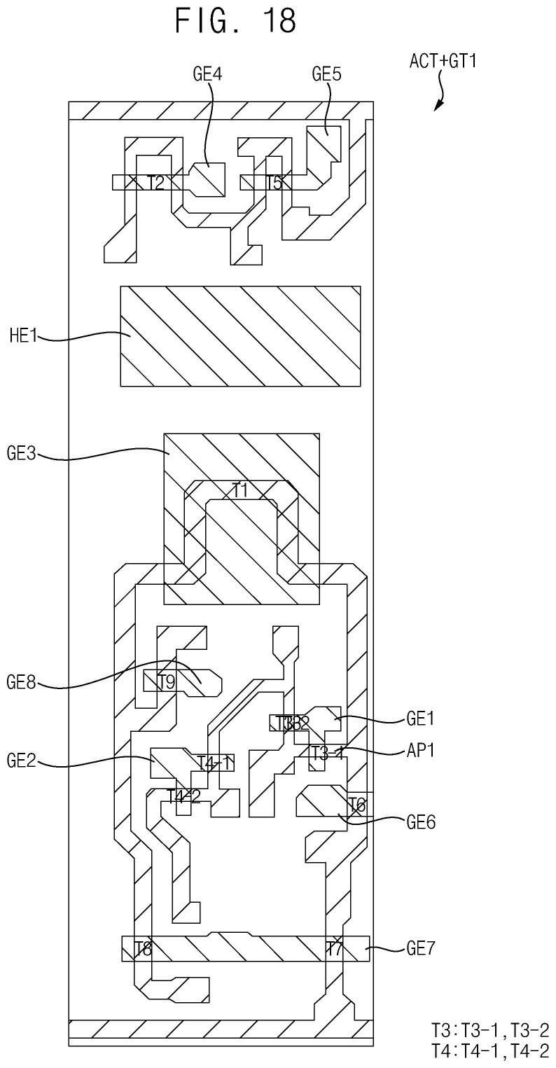

FIG. 17 is a layout diagram illustrating a first gate layer included in a pixel. FIG. 18 is a layout diagram illustrating the active layer of FIG. 16 and the first gate layer of FIG. 17.

Further referring to FIGS. 17 and 18, a first gate layer GT1 may be disposed on the first insulating layer IL1. The first gate layer GT1 may include a first gate electrode GE1, a second gate electrode GE2, a third gate electrode GE3, a fourth gate electrode GE4, a fifth gate electrode GE5, a sixth gate electrode GE6, a seventh gate electrode GE7, an eighth gate electrode GE8, and a first hold electrode HE1.

The first gate electrode GE1 may be disposed on the first active pattern AP1. The first gate electrode GE1 may partially overlap the first active pattern AP1. The first gate electrode GE1 and the first active pattern AP1 may constitute the third transistor T3. The third transistor T3 may be a dual transistor.

The second gate electrode GE2 may be disposed on the second active pattern AP2. The second gate electrode GE2 may be spaced apart from the first gate electrode GE1. The second gate electrode GE2 may partially overlap the second active pattern AP2. The second gate electrode GE2 and the second active pattern AP2 may constitute the fourth transistor T4. The fourth transistor T4 may be a dual transistor.

A second insulating layer (e.g., the second insulating layer IL2 of FIG. 14) may be disposed on the first insulating layer. The second insulating layer may cover the first gate layer GT1.

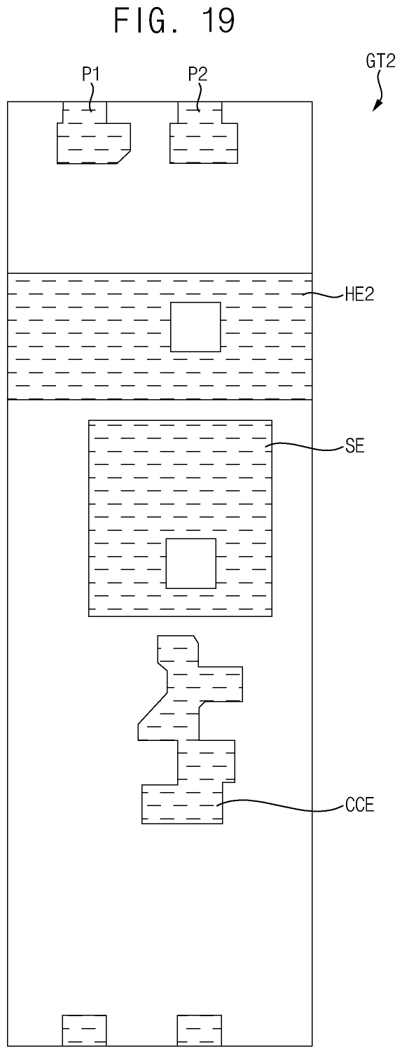

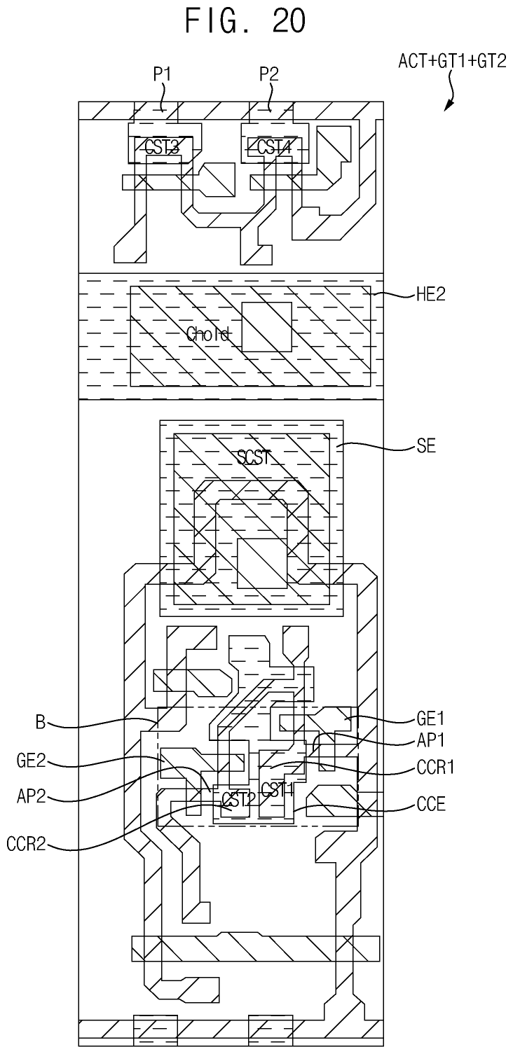

FIG. 19 is a layout view illustrating a second gate layer included in a pixel. FIG. 20 is a layout view illustrating the active layer of FIG. 16, the first gate layer of FIG. 17, and the second gate layer of FIG. 19.

Further referring to FIGS. 19 and 20, a second gate layer GT2 may be disposed on the second insulating layer. The second gate layer GT2 may include a common capacitor electrode CCE, a storage electrode SE, a second hold electrode HE2, and stabilization electrodes P1 and P2.

In an embodiment, the common capacitor electrode CCE may be disposed on the first active pattern AP1 and the second active pattern AP2. The common capacitor electrode CCE may overlap the first active pattern AP1 and the second active pattern AP2.

The stabilization electrodes P1 and P2 may overlap the fourth and fifth active patterns AP4 and AP5, respectively. In addition, the stabilization electrodes P1 and P2 and the fourth and fifth active patterns AP4 and AP5 may constitute the third capacitor CST3 and the fourth capacitor CST4, respectively.

For example, the stabilization electrodes P1 and P2 may include a first stabilization electrode P1 and a second stabilization electrode P2. The first stabilization electrode P1 and the fourth active pattern AP4 may constitute the third capacitor CST3. The second stabilization electrode P2 and the fifth active pattern AP5 may constitute the fourth capacitor CST4. However, the present disclosure is not limited thereto.

In an embodiment, the capacitance of the third capacitor CST3 may be different from the capacitance of the fourth capacitor CST4. For example, the capacitance of the third capacitor CST3 may be greater than the capacitance of the fourth capacitor CST4. For another example, the capacitance of the third capacitor CST3 may be smaller than the capacitance of the fourth capacitor CST4.

To make the capacitance of the third capacitor CST3 and the capacitance of the fourth capacitor CST4 different from each other, areas of the stabilizing electrodes P1 and P2 overlapping the fourth active pattern AP4 and the fifth active pattern AP5 may be different from each other. For example, an area where the first stabilization electrode P1 overlaps the fourth active pattern AP4 may be greater than an area where the second stabilization electrode P2 overlaps the fifth active pattern AP5. In this case, the capacitance of the third capacitor CST3 may be greater than the capacitance of the fourth capacitor CST4. However, the present disclosure is not limited thereto, and in another embodiment, the area where the first stabilization electrode P1 overlaps the fourth active pattern AP4 may be smaller than the area where the second stabilization electrode P2 overlaps the fifth active pattern AP5. In this case, the capacitance of the third capacitor CST3 may be smaller than the capacitance of the fourth capacitor CST4.

A third insulating layer (e.g., the third insulating layer IL3 of FIG. 14) may be disposed on the second insulating layer. The third insulating layer may cover the second gate layer GT2.

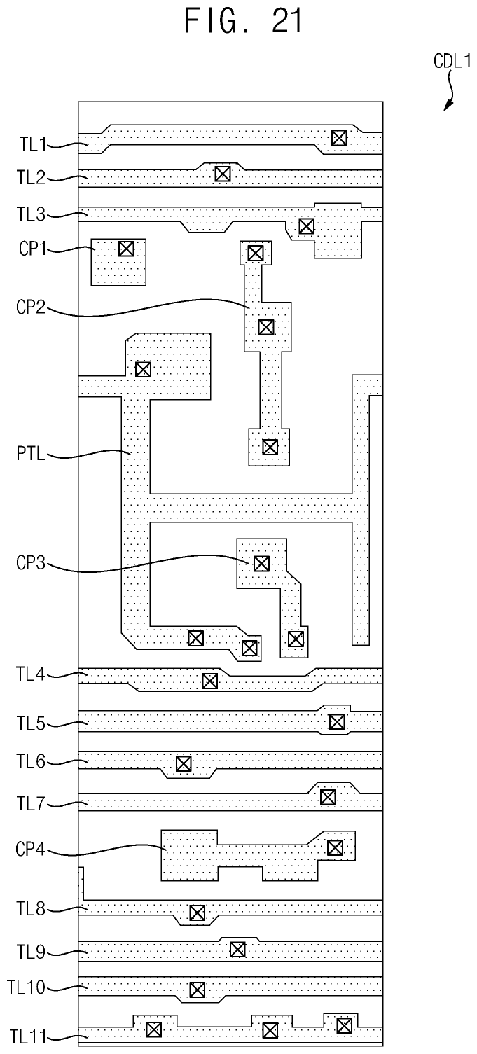

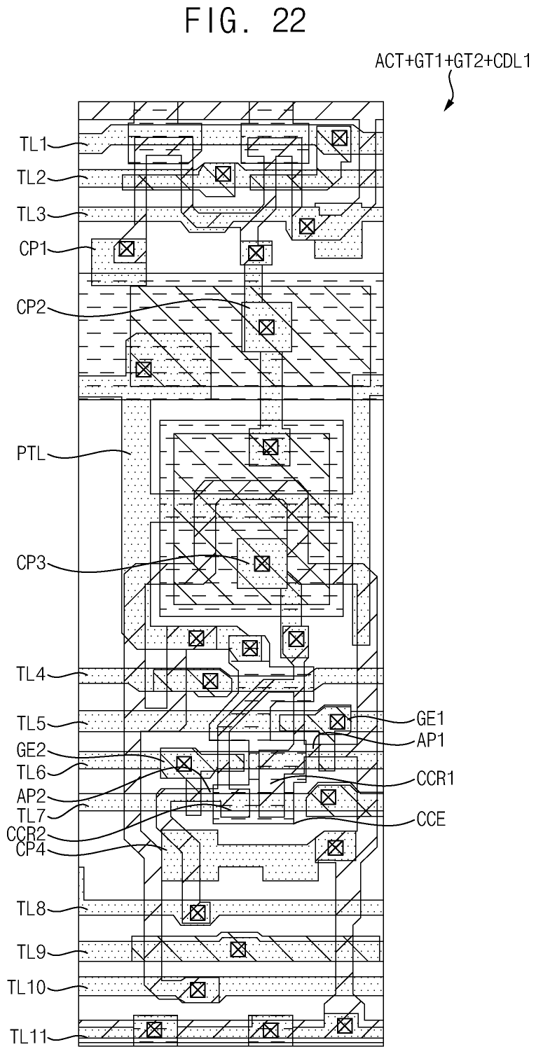

FIG. 21 is a layout view illustrating a first conductive layer included in a pixel. FIG. 22 is a layout view illustrating the active layer of FIG. 16, the first gate layer of FIG. 17, the second gate layer of FIG. 19, and the first conductive layer of FIG. 21.

Further referring to FIGS. 21 and 22, a first conductive layer CDL1 may be disposed on the third insulating layer. The first conductive layer CDL1 may include first, second, third, fourth, fifth, sixth, seventh, eighth, ninth, tenth, and eleventh transfer lines TL1, TL2, TL3, TL4, TL5, TL6, TL7, TL8, TL9, TL10, and TL11, first, second, third, and fourth connection patterns CP1, CP2, CP3, and CP4, and a power transfer line PTL.

In an embodiment, the power transfer line PTL may be connected to the second hold electrode HE2, the ninth active pattern AP9, and the common capacitor electrode CCE.

A fourth insulating layer may be disposed on the third insulating layer. The fourth insulating layer may cover the first conductive layer CDL1.

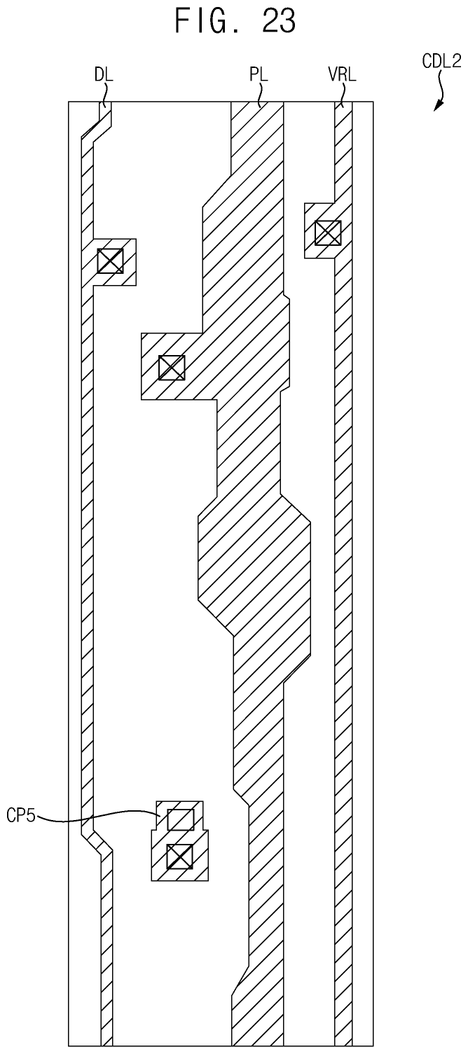

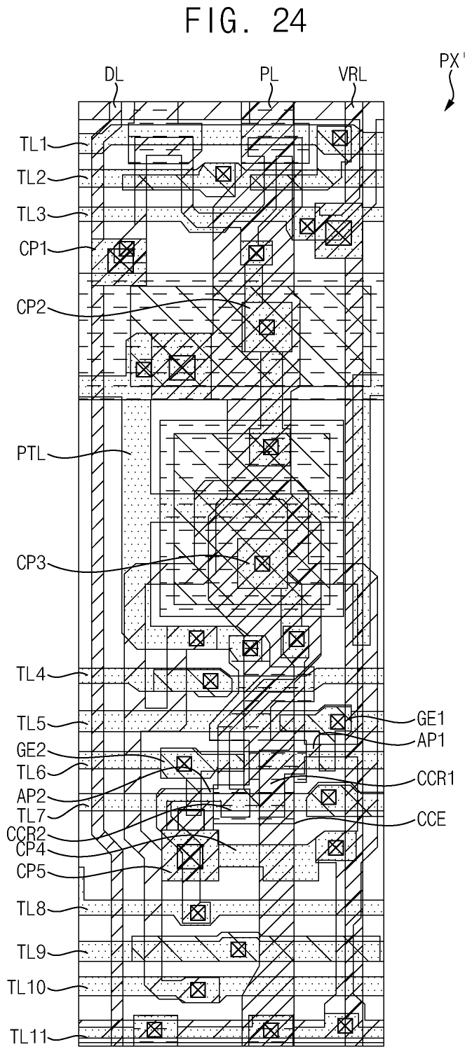

FIG. 23 is a layout view illustrating a second conductive layer included in a pixel. FIG. 24 is a layout view illustrating the active layer of FIG. 16, the first gate layer of FIG. 17, the second gate layer of FIG. 19, the first conductive layer of FIG. 21, and the second conductive layer of FIG. 23. For example, FIG. 24 may be a layout view illustrating the pixels PX′.

Further referring to FIGS. 23 and 24, the second conductive layer CDL2 may be disposed on the fourth insulating layer. The second conductive layer CDL2 may include a data line DL, a power line PL, a reference voltage line VRL, and a fifth connection pattern CP5.

The power line PL may transfer the first voltage ELVDD. The power line PL may be connected to the power transfer line PTL. That is, the power line PL may be connected to the common capacitor electrode CCE through the power transfer line PTL. The power line PL may transfer the first voltage ELVDD to the second hold electrode HE2, the ninth active pattern AP9, and the common capacitor electrode CCE through the power transfer line PTL.

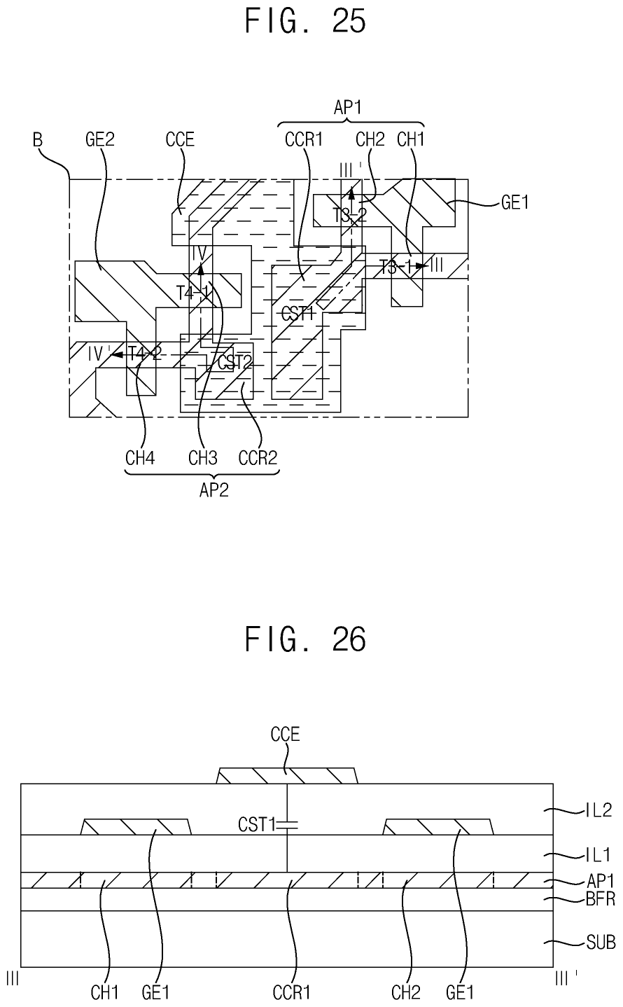

FIG. 25 is an enlarged plan view of area B of FIG. 20. FIG. 26 is a cross-sectional view taken along line III-III′ of FIG. 25.

For example, only the common capacitor electrode CCE, the first gate electrode GE1, the second gate electrode GE2, the first active pattern AP1, and second active pattern AP2 of FIG. 20 may be shown in FIG. 25.

Referring to FIGS. 2 and 25, the first active pattern AP1 may include a first channel region CH1, a second channel region CH2, and a first common conductive region CCR1. The first channel region CH1 and the second channel region CH2 may be spaced apart from each other. The first common conductive region CCR1 may be positioned between the first channel region CH1 and the second channel region CH2.

The third transistor T3 may include a first sub-transistor T3-1 and a second sub-transistor T3-2. The first sub-transistor T3-1 may include the first channel region CH1 and the first gate electrode GE1. The second sub-transistor T3-2 may include the second channel region CH2 and the first gate electrode GE1. The first gate electrode GE1 may overlap each of the first channel region CH1 and the second channel region CH2.

The first common conductive region CCR1 may overlap the common capacitor electrode CCE. The first common conductive region CCR1 may constitute the first capacitor CST1 (e.g., the first capacitor CST1 of FIG. 2) together with the common capacitor electrode CCE.

The second active pattern AP2 may be spaced apart from the first active pattern AP1. The second active pattern AP2 may include a third channel region CH3, a fourth channel region CH4, and a second common conductive region CCR2. The third channel region CH3 and the fourth channel region CH4 may be spaced apart from each other. The second common conductive region CCR2 may be positioned between the third channel region CH3 and the fourth channel region CH4.

The fourth transistor T4 may include a first sub-transistor T4-1 and a second sub-transistor T4-2. The first sub-transistor T4-1 may include the third channel region CH3 and the second gate electrode GE2. The second sub-transistor T4-2 may include the fourth channel region CH4 and the second gate electrode GE2. The second gate electrode GE2 may overlap each of the third and fourth channel regions CH3 and CH4.

The second common conductive region CCR2 may overlap the common capacitor electrode CCE. The second common conductive region CCR2 may constitute the second capacitor CST2 (e.g., the second capacitor CST2 of FIG. 2) together with the common capacitor electrode CCE.

In an embodiment, the second common conductive region CCR2 may have a smaller area than the first common conductive region CCR1. That is, an area where the common capacitor electrode CCE and the first common conductive region CCR1 overlap may be greater than an area where the common capacitor electrode CCE and the second common conductive region CCR2 overlap.

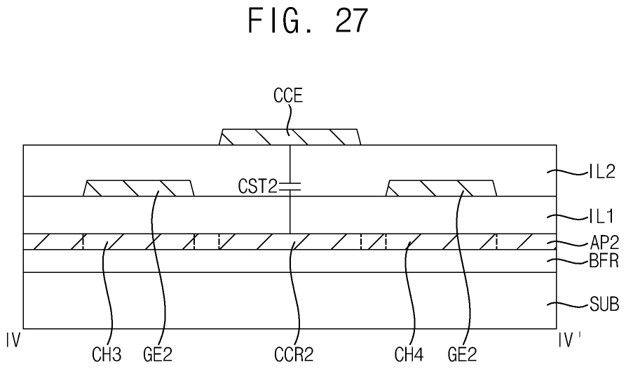

Referring FIGS. 26 and 27, the first capacitor CST1 may include the common capacitor electrode CCE and the first common conductive region CCR1 of the first active pattern AP1 and the second capacitor CST2 may include the common capacitor electrode CCE and the second common conductive region CCR2 of the second active pattern AP2.

Accordingly, a distance between the first active pattern AP1 and the common capacitor electrode CCE may be substantially the same as a distance between the second active pattern AP2 and the common capacitor electrode CCE.

In an embodiment, the area where the common capacitor electrode CCE and the first common conductive region CCR1 overlap may be greater than the area where the common capacitor electrode CCE and the second common conductive region CCR2 overlap. Therefore, the capacitance of the first capacitor CST1 may be greater than the capacitance of the second capacitor CST2.

For example, the range of the ratio of the area where the common capacitor electrode CCE and the first common conductive region CCR1 overlap to the area where the common capacitor electrode CCE and the second common conductive region CCR2 overlap may be greater than about 1 and less than about 5. That is, the range of the ratio of the capacitance of the first capacitor CST1 to the capacitance of the second capacitor CST2 may be greater than about 1 and less than about 5.

When the range of the ratio of the capacitance of the first capacitor CST1 to the capacitance of the second capacitor CST2 is about 1 or less, the amount of leakage current of the third transistor T3 may increase. The voltage of the storage capacitor SCST may be relatively more influenced by the first capacitor CST1 than by the second capacitor CST2. That is, when the capacitance of the first capacitor CST1 is smaller than the capacitance of the second capacitor CST2, it may not be easy to control the leakage current of the third transistor T3. Accordingly, the voltage of the storage capacitor SCST may increase due to the amount of leakage current of the third transistor T3. In this case, the luminance of the display device 10 may be reduced and a low-frequency characteristic of the display device 10 may be deteriorated.

When the range of the ratio of the capacitance of the first capacitor CST1 to the capacitance of the second capacitor CST2 is about 5 or more, the capacitance of the first capacitor CST1 may increase relatively greatly. In this case, it may take a lot of time to charge the first capacitor CST1. Accordingly, charging efficiency of the display device 10 may decrease. Alternatively, when the range of the ratio of the capacitance of the first capacitor CST1 to the capacitance of the second capacitor CST2 is about 5 or more, the capacitance of the second capacitor CST2 may be relatively greatly reduced. In this case, it may not be easy to control the amount of leakage current of the fourth transistor T4. Therefore, the voltage of the storage capacitor SCST may increase due to the amount of leakage current of the fourth transistor T4. In this case, the luminance of the display device 10 may be reduced and a low-frequency characteristic of the display device 10 may be deteriorated.

In an embodiment, the display device 10 may further include the first capacitor CST1 and the second capacitor CST2 in addition to the storage capacitor SCST and the hold capacitor Chold. In this case, since the area where the common capacitor electrode CCE and the first common conductive region CCR1 overlap is greater than the area where the common capacitor electrode CCE and the second common conductive region CCR2 overlap, the capacitance of the first capacitor CST1 may be greater than the capacitance of the second capacitor CST2. The voltage of the storage capacitor SCST may be relatively more influenced by the first capacitor CST1 than by the second capacitor CST2. Therefore, by making the capacitance of the first capacitor CST1 greater than the capacitance of the second capacitor CST2, the leakage current of the third transistor T3 can be maintained less than the leakage current of the fourth transistor T4. As a result, the voltage of the storage capacitor SCST may be maintained constant, and the luminance of the display device 10 may not decrease. In addition, since the flicker phenomenon does not occur, a low-frequency characteristic of the display device 10 can be improved.

A display device according to embodiments of the present disclosure can be applied to display devices included in computers, laptop computers, mobile phones, smart phones, smart pads, automobiles, PMPs, PDAs, MP3 players, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate;
a first active pattern disposed on the substrate and including a first channel region, a second channel region spaced apart from each other, and a first common conductive region positioned between the first channel region and the second channel region;
a second active pattern disposed on the substrate, spaced apart from the first active pattern, and including a third channel region, a fourth channel region spaced apart from each other, and a second common conductive region positioned between the third channel region and the fourth channel region;
a first gate layer disposed on the first active pattern and the second active pattern, and including a first electrode overlapping the first active pattern; and
a second gate layer disposed on the first gate layer and including a second electrode overlapping the second active pattern.

2. The display device of claim 1, wherein the second electrode is spaced apart from the first electrode in a plan view.

3. The display device of claim 1, wherein the first electrode overlaps the first common conductive region and the second electrode overlaps the second common conductive region in a plan view.

4. The display device of claim 3, wherein the first electrode constitutes a first capacitor together with the first common conductive region and the second electrode constitutes a second capacitor together with the second common conductive region.

5. The display device of claim 1, wherein a distance between the first active pattern and the first electrode is smaller than a distance between the second active pattern and the second electrode.

6. The display device of claim 1, wherein the first active pattern and the second active pattern are integrally formed and constitute a first active layer.

7. The display device of claim 6, further comprising:
a second active layer spaced apart from the first active layer; and
two stabilization electrodes disposed on the second active layer and overlapping the second active layer,
wherein the second active layer and the stabilization electrodes constitute a third capacitor and a fourth capacitor, respectively.

8. The display device of claim 7, wherein a capacitance of the third capacitor is different from a capacitance of the fourth capacitor.

9. The display device of claim 1, wherein the first gate layer includes a first gate electrode partially overlapping the first active pattern and a second gate electrode partially overlapping the second active pattern.

10. The display device of claim 9, wherein the first gate electrode overlaps the first channel region and the second channel region of the first active pattern, and
the second gate electrode overlaps the third channel region and the fourth channel region of the second active pattern.

11. The display device of claim 1, further comprising:
a power line disposed on the second gate layer and connected to each of the first electrode and the second electrode.

12. A display device comprising:
a substrate;
a first active pattern disposed on the substrate and including a first channel region, a second channel region spaced apart from each other, and a first common conductive region positioned between the first channel region and the second channel region;
a second active pattern disposed on the substrate, spaced apart from the first active pattern, and including a third channel region, a fourth channel region spaced apart from each other, and a second common conductive region positioned between the third channel region and the fourth channel region and having a smaller area than the first common conductive region;
a first gate layer disposed on the first active pattern and the second active pattern; and
a second gate layer disposed on the first gate layer and including a common capacitor electrode overlapping the first active pattern and the second active pattern.

13. The display device of claim 12, wherein the common capacitor electrode overlaps the first common conductive region and the second common conductive region in a plan view.

14. The display device of claim 12, wherein the first active pattern and the second active pattern are integrally formed and constitute an active layer.

15. The display device of claim 14, wherein the common capacitor electrode constitutes a first capacitor together with the first common conductive region and constitutes a second capacitor together with the second common conductive region.

16. The display device of claim 15, wherein an area where the common capacitor electrode and the first common conductive region overlap is greater than an area where the common capacitor electrode and the second common conductive region overlap.

17. The display device of claim 16, wherein a range of a ratio of the area where the common capacitor electrode and the first common conductive region overlap to the area where the common capacitor electrode and the second common conductive region overlap is greater than about 1 and smaller than about 5.

18. The display device of claim 12, wherein the first gate layer includes a first gate electrode partially overlapping the first active pattern and a second gate electrode partially overlapping the second active pattern, and
the first gate electrode and the second gate electrode are spaced apart from each other.

19. The display device of claim 18, wherein the first gate electrode overlaps the first channel region and the second channel region of the first active pattern, and
the second gate electrode overlaps the third channel region and the fourth channel region of the second active pattern.

20. The display device of claim 12, further comprising:
a power line disposed on the second gate layer and connected to the common capacitor electrode.
